(19) United States
(12) Patent Application Publication
(10) Pub. No.: US 2019/0082084 A1
(43) Pub. Date: Mar. 14, 2019

(54) Image Sensor Modules Having Support Structures

(71) Applicant: Samsung Electronics Co., Ltd., Suwon-si (KR)

(72) Inventor: Shle Ge Lee, Seoul (KR)

(21) Appl. No.: 15/958,522

(22) Filed: Apr. 20, 2018

(30) Foreign Application Priority Data
Sep. 12, 2017 (KR) 10-2017-0116396

(51) Int. Cl. H04N 5/225; H01L 23/02; H01L 25/03; H01L 27/146; H01L 23/00

(52) U.S. Cl. CPC H04N 5/2253; H01L 23/02; H01L 24/01; H01L 27/14601; H01L 25/03

(57) ABSTRACT

Image sensor modules are provided including a lower structure, and an upper structure on the lower structure. The image sensor module further includes a semiconductor substrate in which an image sensor is formed. The lower structure includes a semiconductor chip on a region of a lower surface of the upper structure and connected to the image sensor; a reinforcing frame along an edge of the lower surface of the upper structure; and a resin molding portion between the reinforcing frame and the semiconductor chip. The reinforcing frame has a Young's modulus higher than a Young's modulus of the resin molding portion.

### CLAIM OF PRIORITY

This application claims the benefit of priority to Korean Patent Application No. 10-2017-0116396, filed Sep. 12, 2017 in the Korean Intellectual Property Office, the disclosure of which is hereby incorporated herein by reference as if set forth in its entirety.

### FIELD

The present inventive concept relates generally to image sensors and, more particularly, to image sensor modules have support structures.

### BACKGROUND

An image sensor module is an apparatus for capturing light, forming an image, and converting the light into an electrical signal. The image sensor module may be used in a mobile device such as a digital camera, in a camera of a mobile phone or a smartphone, in a portable camcorder, as well as in a camera mounted in a vehicle, a security device, a robot, or the like. Such an image sensor module may be required to be as small as possible and to have improved resolution. Furthermore, these images sensors generally need to be durable enough to withstand mechanical/thermal impacts in a use environment such as a mobile device, or the like.

### SUMMARY

Some embodiments of the present inventive concept provide an image sensor module including a lower structure and an upper structure on the lower structure. The image sensor module includes a semiconductor substrate having an image sensor therein.

In further embodiments, the lower structure may include a semiconductor chip on a region of a lower surface of the upper structure and connected to the image sensor; a reinforcing frame disposed along an edge of the lower surface of the upper structure; and a resin molding portion disposed between the reinforcing frame and the semiconductor chip. The reinforcing frame may have a Young's modulus higher than a Young's modulus of the resin molding portion.

In still further embodiments, an image sensor module may include an upper structure including a first semiconductor substrate including and image sensor and a second semiconductor substrate including a logic circuit; and a lower structure on a lower surface of the upper structure having side surfaces that are substantially coplanar with side surfaces of the upper structure, adjacent thereto. In these embodiments, the lower structure may include a semiconductor chip connected to the image sensor and the logic circuit, a resin molding portion configured to surround the semiconductor chip, and a reinforcing frame providing side surfaces of the lower structure while surrounding the resin molding portion, and having Young's modulus higher than Young's modulus of the resin molding portion.

In some embodiments of the present inventive concept, an image sensor module may include an upper structure including a first semiconductor substrate including an image sensor and a second semiconductor substrate including a logic circuit; and a lower structure on a lower surface of the upper structure, and of which side surfaces are substantially coplanar with side surfaces of the upper structure, adjacent thereto. In these embodiments, the lower structure may include a first reinforcing frame and a second reinforcing frame provided as one pair of side surfaces of the lower structure, opposing each other, a semiconductor chip disposed between the first reinforcing frame and the second reinforcing frame and connected to the image sensor and the logic circuit, and a resin molding portion disposed between the first reinforcing frame and the second reinforcing frame to surround the semiconductor chip and provided as the other pair of side surfaces of the lower structure, opposing each other.

### BRIEF DESCRIPTION OF DRAWINGS

The above and other aspects, features and other advantages of the present inventive concept will be more clearly understood from the following detailed description, taken in conjunction with the accompanying drawings, in which:

FIG. 1 is an exploded perspective view illustrating an image sensor module according to some embodiments of the present inventive concept.

FIG. 2 is a side cross section along the line I-I′ illustrating the image sensor module illustrated in FIG. 1 according to some embodiments of the present inventive concept.

FIG. 3 is a detailed side cross section illustrating the image sensor module illustrated in FIG. 2 in detail according to some embodiments of the present inventive concept.

FIG. 4 is a diagram illustrating a camera module including the image sensor module illustrated in FIG. 1 according to some embodiments of the present inventive concept.

FIG. 5 is a graph illustrating a change in applied stress due to a width of a reinforcing frame employable in accordance with some embodiments of the present inventive concept.

FIG. 6 is a graph illustrating a change in applied stress due to strength of a reinforcing frame employable in accordance with some embodiments of the present inventive concept.

FIGS. 7A and 7B are a cross section (II-II′) and plan view, respectively, of an image sensor module according to some embodiments of the present inventive concept.

FIGS. 8A and 8B are a cross section (III-III′) and plan view, respectively, of a lower structure of the image sensor module according to some embodiments of the present inventive concept.

### DETAILED DESCRIPTION

The inventive concept will now be discussed more fully hereinafter with reference to the accompanying drawings, in which exemplary embodiments of the inventive concept are shown. The inventive concept and methods of achieving them will be apparent from the following exemplary embodiments that will be discussed in more detail with reference to the accompanying drawings. The embodiments of the inventive concept may, however, be embodied in different forms and should not be constructed as limited to the embodiments set forth herein. Rather, these embodiments are provided so that this disclosure will be thorough and complete, and will fully convey the scope of the inventive concept to those skilled in the art.

The terminology used herein is for the purpose of describing particular embodiments only and is not intended to limit the inventive concept. As used herein, the singular terms “a,” “an” and “the” are intended to include the plural forms as well, unless the context clearly indicates otherwise. As used herein, the term “and/or” includes any and all combinations of one or more of the associated listed items.

Similarly, it will be understood that when an element such as a layer, region or substrate is referred to as being “on” another element, it can be directly on the other element or intervening elements may be present. In contrast, the term “directly” means that there are no intervening elements. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof. Additionally, exemplary embodiments are discussed herein with reference to cross-sections and/or plan views that are idealized exemplary views. Accordingly, shapes of exemplary views may be modified according to manufacturing techniques and/or allowable errors. Therefore, the embodiments of the inventive concept are not limited to the specific shape illustrated in the exemplary views, but may include other shapes that may be created according to manufacturing processes.

Also, though terms “first” and “second” are used to describe various members, components, regions, layers, and/or portions in various embodiments of the inventive concepts, the members, components, regions, layers, and/or portions are not limited to these terms. These terms are used only to differentiate one member, component, region, layer, or portion from another one. Therefore, a member, a component, a region, a layer, or a portion referred to as a first member, a first component, a first region, a first layer, or a first portion in an embodiment may be referred to as a second member, a second component, a second region, a second layer, or a second portion in another embodiment.

Unless otherwise defined, all terms used herein, including technical and scientific terms, have the same meaning as commonly understood by one of ordinary skill in the art to which the inventive concepts belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Exemplary embodiments of aspects of the present inventive concept explained and illustrated herein include their complementary counterparts. The same reference numerals or the same reference designators denote the same elements throughout the specification.

Hereinafter, embodiments of the inventive concept will be discussed with reference to the accompanying drawings.

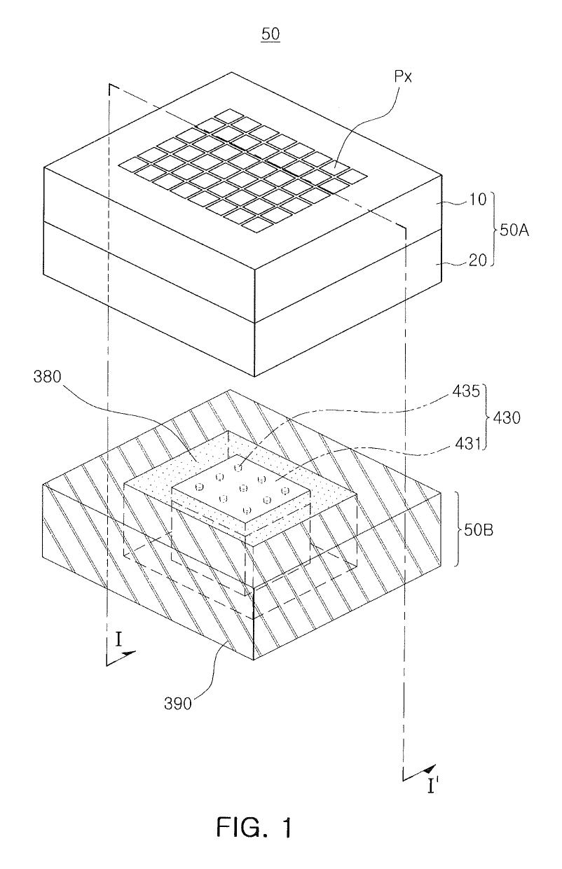

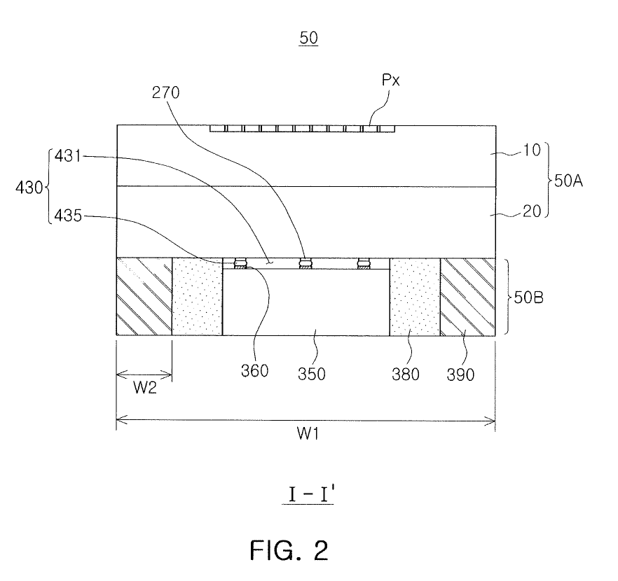

FIG. 1 an exploded perspective view illustrating an image sensor module according to some embodiments of the present inventive concept and FIG. 2 is a side cross section along the line I-I′ illustrating embodiments of the image sensor module in FIG. 1.

Referring to FIGS. 1 and 2, an image sensor module 50 according to an example embodiment may include an upper structure 50A having an image sensor 10, and a lower structure 50B having a semiconductor chip 350 connected to the image sensor 10.

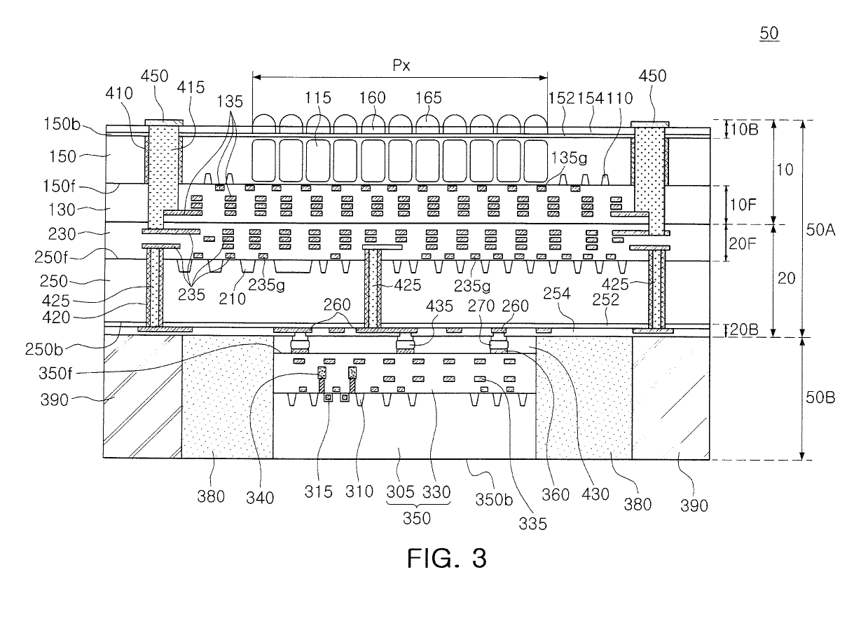

The upper structure 50A in accordance with some embodiments may include a logic circuit portion 20 connected to the image sensor 10. Furthermore, the image sensor 10 may include a pixel array PX. The image sensor 10 and the logic circuit portion 20 may be configured to include semiconductor substrates (see e.g. 150 and 250 of FIG. 3), respectively. Structures of the image sensor 10 and the logic circuit portion 20 will be described with reference to FIG. 3 below.

The lower structure 50B is disposed on a lower surface of the upper structure 50A. Side surfaces of the lower structure 50B may be substantially coplanar with side surfaces of the upper structure 50A, adjacent thereto.

The lower structure 50B may include the semiconductor chip 350 disposed in a region of a lower surface of the upper structure 50A, a reinforcing frame 390 disposed along an edge of the lower surface of the upper structure 50A, and a resin molding portion 380 disposed between the reinforcing frame 390 and the semiconductor chip 350.

In some embodiments, the semiconductor chip 350 may be a memory chip capable of storing image information captured by the image sensor 10 and processed by the logic circuit portion 20. For example, the semiconductor chip 350 may include a dynamic random-access memory (DRAM).

The semiconductor chip 350 may be connected to the logic circuit portion 20 of the upper structure 50A through a connection structure layer 430. In detail, first connection pads 270 disposed on a lower surface of the logic circuit portion 20 and second connection pads 360 disposed on an upper surface of the semiconductor chip 350 may be located in the connection structure layer 430. The first connection pads 270 of the logic circuit portion 20 and the second connection pads 360 of the semiconductor chip 350 may be connected by a connective conductor 435 such as a solder ball. An insulating material 431, such as a non-conducting film (NCF), may be introduced between the logic circuit portion 20 and the semiconductor chip 350.

The resin molding portion 380 may be disposed on a lower surface of the upper structure 50A to surround the semiconductor chip 350. The resin molding portion 380 is not limited, and may be an epoxy resin such as an epoxy molding compound (EMC).

As illustrated in FIG. 1, the reinforcing frame 390 may be disposed along all edges (four edges) of a lower surface of the upper structure 50A to surround the resin molding portion 380. The semiconductor chip 350 and the resin molding portion 380 may be disposed in an internal space surrounded by the reinforcing frame 390. As described above, the reinforcing frame 390 may be an outermost structure of the lower structure 50B, provided as a side surface of the lower structure 50B.

The reinforcing frame 390 may be formed of a material having Young's modulus higher than that of the resin molding portion 380 to have durability to impacts applied during mounting or using. Thus, the upper structure 50A having a semiconductor substrate having brittleness is supported using the reinforcing frame 390 of the lower structure 50B, so the likelihood of cracking occurring in the upper structure 50A may be reduced, or possibly prevented.

The reinforcing frame 390 may have sufficient strength to withstand external impacts. For example, the reinforcing frame 390 may have Young's modulus of 50 Gpa or more. The reinforcing frame 390 may be formed of a ceramic or metal. In some embodiments, the reinforcing frame 390 may include stainless steel such as steel use stainless (SUS) (see FIG. 6).

When pressure is applied to a lower surface of the lower structure 50B, in order to allow a lower surface of the reinforcing frame 390 to be in contact with a pressure applying device, the reinforcing frame 390 may be provided as a structure, having a substantially flat surface coplanar with lower surfaces of the resin molding portion 380 and the semiconductor chip 350 or having a surface, a level of which is higher.

Meanwhile, although there may be a difference depending on a contact area of a pressure applying device, in order not to be in contact with only the resin molding portion 380 or the semiconductor chip 350, an appropriate width may be set to allow the reinforcing frame to have a sufficient area.

As illustrated in FIG. 2, a width W2 of the reinforcing frame 390 may be 10% or more of a width W1 of the lower structure 50B. In an example embodiment, the width W2 of the reinforcing frame 390 may be about 900 μm or more.

Referring now to FIG. 3, a detailed side cross section illustrating the image sensor module illustrated in FIG. 2 will be discussed. As illustrated in FIGS. 2 and 3, the image sensor module 50 may include the upper structure 50A including a first semiconductor substrate 150 in which the image sensor 10 is formed and a second semiconductor substrate 250 in which the logic circuit portion 20 is formed, and the lower structure 50B disposed on a lower surface of the upper structure 50A and including the semiconductor chip 350 such as a memory chip.

The image sensor module 50 according to some embodiments may be understood as a 3 stack structure including a first chip forming the image sensor 10, a second chip forming the logic circuit portion 20, and the semiconductor chip 350 provided as the lower structure 50B.

As illustrated in FIG. 3, the image sensor 10 may include the first semiconductor substrate 150 having a first side 150f and a second side 150b opposing each other, as well as a first portion 10F and a second portion 10B disposed in the first side 150f and the second side 150b, respectively. Photoelectric elements 115 may be implemented in the first semiconductor substrate 150. In some embodiments, a first side and a second side of the first semiconductor substrate 150, opposing each other, may be represented by a ‘front side’ and a ‘back side’, respectively.

The photoelectric elements 115 may be a silicon photodiode or a silicon photoelectric conversion element. The photoelectric elements 115 may be arranged in a row direction and a column direction in a similar manner to the pixel array PX illustrated in FIG. 1. In some embodiments, a region in which the photoelectric elements 115 are arranged may be defined as ‘the pixel array PX’. Thus, the pixel array PX may be understood as a region including the photoelectric elements 115.

The first portion 10F may be disposed on the first side 150f of the first semiconductor substrate 150. The first portion 10F may include a first side insulating layer 130 of the first side 150f of the first semiconductor substrate 150 and a first side conductive pattern 135 of the first side insulating layer 130. The first side conductive pattern 135 may be formed to have a multilayer structure. A circuit of the first side conductive pattern 135, close to the first side 150f of the first semiconductor substrate 150, may be upper gate conductive patterns 135g. Shallow trench element isolation regions 110 may be disposed in the first side 150f of the first semiconductor substrate 150.

The second portion 10B may be disposed on the second side 150b of the first semiconductor substrate 150. The second portion 10B may include a second side lower insulating layer 152 on the second side 150b of the first semiconductor substrate 150, a second side upper insulating layer 154 on the second side lower insulating layer 152, color filters 160 in the second side upper insulating layer 154, and microlenses 165 on the color filters 160. The photoelectric elements 115, the color filters 160, and the microlenses 165 may overlap each other.

The logic circuit portion 20 may include the second semiconductor substrate 250 having a first side 250f and a second side 250b, opposing each other, as well as a first portion 20F and a second portion 20B disposed in the first side 250f and the second side 250b, respectively.

The first portion 20F may be disposed on the first side 250f of the second semiconductor substrate 250. The first portion 20F may include a first side insulating layer 230 disposed on the first side 250f of the second semiconductor substrate 250, and a first side conductive pattern 235 located in the first side insulating layer 230. The first side conductive pattern 235 may be formed to have a multilayer structure. A circuit of the first side conductive pattern 235, close to the first side 250f of the second semiconductor substrate 250, may be lower gate conductive patterns 235g. Shallow trench element isolation regions 210 may be disposed in the first side 250f of the second semiconductor substrate 250.

The second portion 20B may be disposed on the second side 250b of the second semiconductor substrate 250. The second portion 20B may include a second side lower insulating layer 252 disposed on the second side 250b of the second semiconductor substrate 250, a second side conductive pattern 260 on the second side lower insulating layer 252, and a second side upper insulating layer 254 covering the second side conductive pattern 260. For example, the first side conductive pattern 235 and the second side conductive pattern 260 may be formed of a conductive material, such as Ti, TiN, and/or Cu, or the like.

The logic circuit portion 20 may include back pads passing through the second side upper insulating layer 254 and electrically connected to the second side conductive pattern 260, that is, first connection pads 270.

The lower structure 50B may include a semiconductor chip 350, a resin molding portion 380 surrounding the semiconductor chip 350, and a reinforcing frame 390 surrounding the resin molding portion 380.

The semiconductor chip 350 used in accordance with some embodiments may be a memory element, such as DRAM. The semiconductor chip 350 may include a third semiconductor substrate 305 having a first side 350f and a second side 350b, opposing each other, a first side insulating layer 330 disposed on an upper surface of the third semiconductor substrate 305, a first side conductive pattern 335 in the first side insulating layer 330, and front pads on the first side insulating layer 330, that is, second connection pads 360.

Furthermore, the semiconductor chip 350 may include shallow trench element isolation regions 310 disposed on an upper surface of the third semiconductor substrate 305, and embedded gates 315 adjacent to an upper surface of the third semiconductor substrate 305.

In some embodiments, the semiconductor chip 350 may include information storage elements 340 disposed in the first side insulating layer 230. For example, the information storage elements 340 may be memory cell capacitors of DRAM. However, the technical idea of the present inventive concept is not limited thereto. The information storage elements 340 may include a material capable of storing information using a resistance change, for example, a phase change material.

As discussed above, the image sensor module 50 may include a connective conductor 435 such as a solder ball, disposed between the first connection pads 270 of the logic circuit portion 20 and the second connection pads 360 of the semiconductor chip 350, and electrically connecting the first connection pads 270 to the second connection pads 360. Thus, the logic circuit portion 20 and the semiconductor chip 350 may be electrically connected to each other. Side surfaces of the connective conductors 435 may be surrounded by the insulating material 431 such as NCF.

In some embodiments, the logic circuit portion 20 may include lower through electrodes 425 passing through the second semiconductor substrate 250. The lower through electrodes 425 may allow the first side conductive pattern 235 in the first portion 20F and the second side conductive pattern 260 in the second portion 20B to be electrically connected to each other. The logic circuit portion 20 may include a lower insulating spacer 420 interposed between the lower through electrodes 425 and the second semiconductor substrate 250, and insulating the lower through electrodes 425 from the second semiconductor substrate 250.

In some embodiments, the image sensor 10 may include upper through electrodes 415 passing through the second portion 10B and the first semiconductor substrate 150 and electrically connected to the first side conductive pattern 135 in the first portion 10F. The upper through electrodes 415 may pass through the second portion 10B not overlapping the pixel array PX to be exposed. External connection pads 450 may be formed in exposed regions of the upper through electrodes 415.

Upper insulating spacers 410 electrically insulating the upper through electrodes 415 from the first semiconductor substrate 150 may be disposed between the upper through electrodes 415 and the first semiconductor substrate 150.

In some embodiments, the upper through electrodes 415 may be extended to an interior of the first portion 20F of the logic circuit portion 20 and may be electrically connected to the first side conductive pattern 235 in the first portion 20F of the logic circuit portion 20. Thus, the image sensor 10, the logic circuit portion 20, and the semiconductor chip 350 of the lower structure 50B may be electrically connected to each other.

The upper structure 50A having the first semiconductor substrate 150 and the second semiconductor substrate 250 in which cracking may easily occur is supported using the reinforcing frame 390 of the lower structure 50B, so durability of the image sensor module 50 may be significantly enhanced.

The reinforcing frame 390 used in some embodiments may have sufficient strength to withstand external impacts. For example, the reinforcing frame 390 may have Young's modulus of 50 Gpa or more. The reinforcing frame 390 may be formed of a ceramic or metal. In some embodiments, the reinforcing frame 390 may include stainless steel such as SUS.

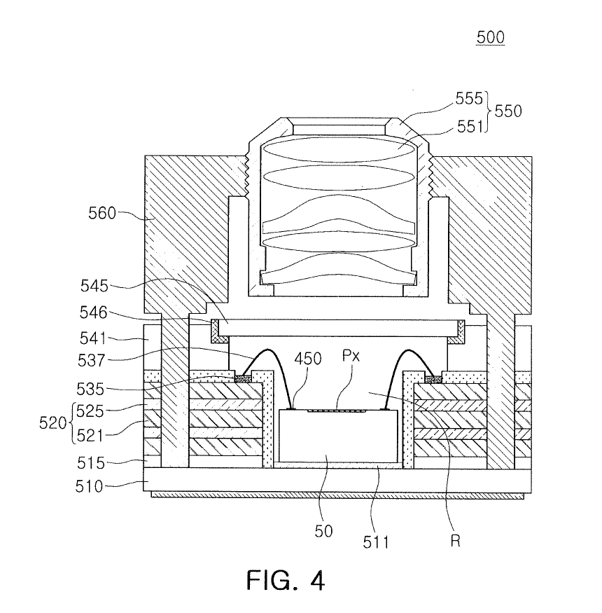

Referring now to FIG. 4, a diagram illustrating a camera module including the image sensor module illustrated in FIG. 1 will be discussed. As illustrated therein, a camera module 500 according to some embodiments may include an image sensor module 50 mounted on a substrate 510 and a lens portion 550 disposed above the image sensor module 50.

A circuit portion 520 having a concave portion R accommodating the image sensor module 50 may be disposed on the substrate 510. The circuit portion 520 may have a multilayer structure including a plurality of insulating layers 521 and a plurality of circuit layers 525, may be provided as, for example, a copper clad laminate (CCL). The circuit portion 520 may be attached to the substrate 510 by an adhesive layer 515.

The image sensor module 50 may be mounted by an adhesive 511 such as epoxy resin on a region of the substrate 510, having been exposed to a concave portion R of the circuit portion 520. External connection pads 450 of the image sensor module 50 may be connected to connection pads 535 of the circuit portion, respectively, using a wire 537.

As illustrated in FIG. 4, the lens portion 550 may include a plurality of lenses 551 and a barrel holder 555 supporting the plurality of lenses, and an actuator for autofocusing 560 may be disposed around the lens portion 550. An optical filter 545 may be included below the lens portion 550, and the optical filter 545 may be mounted on a support structure 541 by an adhesive film 546.

Thus, considerable pressure may be applied while the camera module 500 is mounted on a board of a mobile device, such as a mobile phone, a smartphone, or the like. During a mounting process, cracking may occur in a semiconductor substrate forming an image sensor. However, in the image sensor module 50, according to some embodiments of the present inventive concept, the upper structure 50A, including an image sensor, is supported using the lower structure 50B having a reinforcing frame, so the likelihood of cracking, which may occur in the upper structure 50A, may be reduced, or possibly prevented from occurring. Furthermore, strong durability against stress caused by a drop impact or thermal shock, which may occur in a usage environment, such as a mobile device, or the like, may be improved.

A reinforcing frame is used in a lower structure, compared to a lower structure according to conventional structure (that is, conventional structure) having only a configuration of a semiconductor chip and a resin molding portion, stress applied to an upper structure may be significantly reduced. For example, a structure in accordance with some embodiments of the present inventive concept may be expected to have an effect of reducing stress by 12% to 18%, as compared to conventional structures.

In particular, several tests were conducted to determine appropriate conditions of a reinforcing frame used in accordance with some embodiments of the present inventive concept.

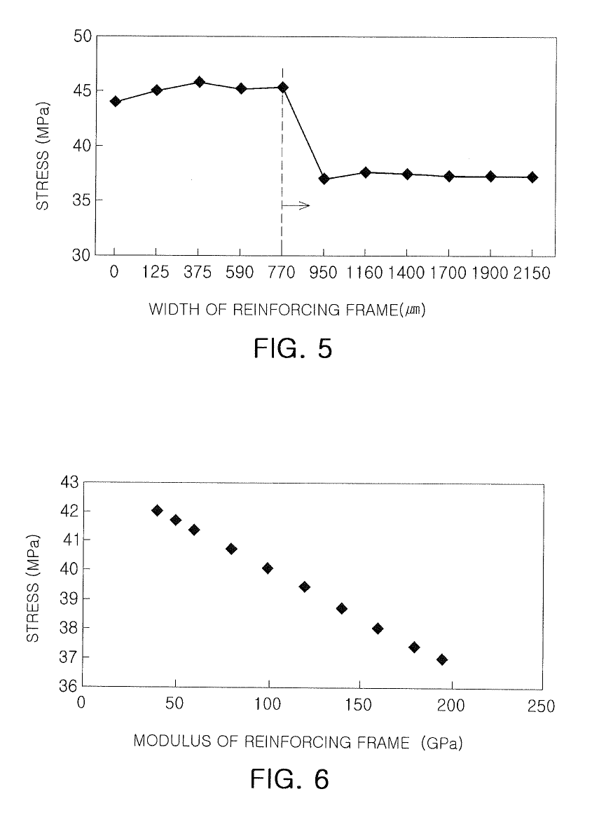

First, a change in applied stress according to a width of a reinforcing frame was measured. In a pressure applying device, a rigid structure in the form of a cylinder, a diameter of which was 6 mm, was used, and pressure was applied in a manner in which an upper surface of a pressure applying device was in contact with a rear side of a lower structure. An image sensor module used in a test had a similar structure (a rectangular reinforcing frame/8 mm×6 mm size) to a module illustrated in FIGS. 1 and 2. A result thereof is illustrated in a graph of FIG. 5.

Referring to FIG. 5, even when a width (see ‘W2’ of FIG. 2) of a reinforcing frame was increased to 800 μm, a level of stress was about 45 Mpa, a level thereof remained high and was not significantly changed. However, after the width passed 800 μm, the level of stress was reduced. Moreover, it was confirmed that the level of stress was significantly reduced to 36 MPa to 37 MPa when the width was 900 μm or more.

Width conditions of a reinforcing frame employed in an example embodiment are able to be changed according to an overall size of an image sensor module. Thus, a sufficient stress reduction effect may be expected by setting a width of a reinforcing frame to be 10% or more of an overall width (see ‘W1’ of FIG. 2) of an image sensor module.

Next, a change in applied stress according to strength of a reinforcing frame was measured. In a structure of the image sensor module illustrated in FIGS. 1 and 2 (a rectangular reinforcing frame/8 mm×6 mm size), a width of a reinforcing frame was set to be 1 mm, and rigidity of the reinforcing frame was changed. Thus, a simulation result of a change in stress obtained as described above is illustrated in FIG. 6.

Referring to FIG. 6, when a Young's modulus of a reinforcing frame is 50 Gpa or more, there was a significant stress reduction effect (about 42 Mpa) compared to stress of a conventional structure (about 45 Mpa). Furthermore, it was confirmed that stress was significantly reduced as Young's modulus was increased. For example, a reinforcing frame according to some embodiments may be formed of a ceramic or metal, and in detail, may include stainless steel such as SUS.

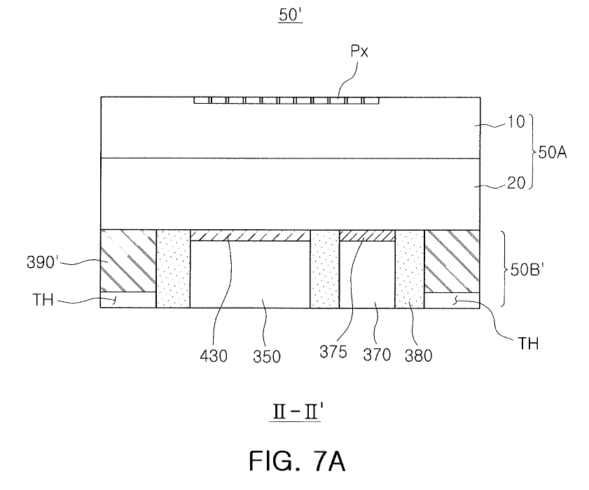

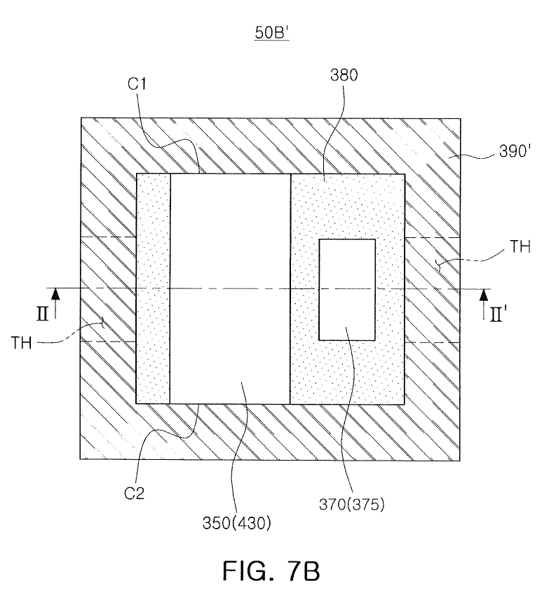

FIG. 7A is a side cross section illustrating an image sensor module according to some embodiments, and FIG. 7B is a plan view of a lower structure of the image sensor module illustrated in FIG. 7A.

Referring to FIGS. 7A and 7B, an image sensor module 50′ according to some embodiments may include an upper structure 50A having an image sensor 10 and a logic circuit portion 20, and a lower structure 50B′ having a semiconductor chip 350, and may be understood as being a similar structure to the image sensor module 50 illustrated in FIGS. 1 through 3.

However, embodiments illustrated in FIGS. 7A and 7B differ from those discussed above in that the lower structure 50B′ includes other elements such as a heat dissipation element 370, a reinforcing frame 390′ has an opening TH connected thereto in a width direction, and a surface of the semiconductor chip 350 is disposed to be in contact with an inner wall of the reinforcing frame 390′. In general, descriptions of the components are the same or similar to components of the image sensor module 50, illustrated in FIGS. 1 through 3, unless specifically stated otherwise and, thus, will not be repeated herein in the interest of brevity.

The lower structure 50B′ is disposed on a lower surface of the upper structure 50A, and may have side surfaces substantially coplanar with side surfaces of the upper structure 50A, adjacent thereto. In some embodiments, the lower structure 50B′ may include the semiconductor chip 350, electrically connected to the image sensor 10 and the logic circuit portion 20 through the connection structure layer 430, as well as the heat dissipation element 370. The heat dissipation element 370 may be disposed on a lower surface of the upper structure 50A using an adhesive layer 375. In a similar manner thereto, in some embodiments, the lower structure 50B′ may further include a plurality of semiconductor chips or another element in an internal space of a reinforcing frame 390′.

Furthermore, the lower structure 50B′ may include the resin molding portion 380 disposed to surround the semiconductor chip 350, and the reinforcing frame 390′ providing side surfaces of the lower structure 50B′ while surrounding the resin molding portion 380. The reinforcing frame 390′ may have Young's modulus higher than Young's modulus of the resin molding portion 380. The reinforcing frame 390′ has the opening TH provided therein in a width direction.

As illustrated in FIG. 7B, the reinforcing frame 390′ may have two openings TH in portions adjacent to two edges opposing each other. The two openings TH may be used as an inlet of a molding resin for formation of the resin molding portion 380. A portion or an entirety of an opening TH may be charged as the resin molding portion 380 is extended thereto.

In particular, in a module manufacturing process, after the semiconductor chip 350, the heat dissipation element 370, and the reinforcing frame 390′ are bonded to a lower surface of the upper structure 50A, in a state in which a bottom surface is covered with the reinforcing frame 390′ (for example, in a state in which the reinforcing frame 390′ is mounted on a bottom surface), the two openings TH may be used as a device for injecting liquid resin for molding, such as epoxy resin, into an internal space of the reinforcing frame 390′.

Two side surfaces of the semiconductor chip 350, opposing each other, may be disposed to be in contact with an inner wall of the reinforcing frame 390′. As illustrated in FIG. 7B, the semiconductor chip 350 and the reinforcing frame may have two contact surfaces C1 and C2. The semiconductor chip 350 may be a memory element such as a DRAM, capable of storing image information. The semiconductor chip 350 may act as a heat source with the logic circuit portion 20, and may have an effect on the image sensor 10 and may then cause a problem such as image distortion.

In particular, due to low thermal conductivity of the resin molding portion 380, located around the semiconductor chip, the semiconductor chip 350, a memory element, may easily radiate heat toward the image sensor 10 located thereabove. To alleviate a problem described above, as at least a surface of the semiconductor chip 350 is in contact with the reinforcing frame 390′, heat, generated by the semiconductor chip 350, may be effectively released through the contact surfaces C1 and C2 toward the reinforcing frame 390′ located in an outermost position.

For example, in a case of the resin molding portion 380, epoxy, thermal conductivity is only 0.2 W/m K. In a case of the reinforcing frame 390′, SUS, thermal conductivity is high, 10 W/m K to 30 W/m K. Thus, the reinforcing frame 390′ employed in an example embodiment may be used as an effective heat dissipation device.

The reinforcing frame used in some embodiments may be modified into various types of structures, in addition to being configured to have an opening TH of injection molding resin as in the previous example embodiment.

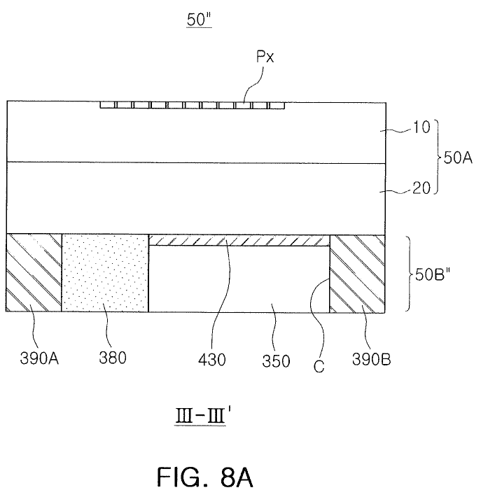

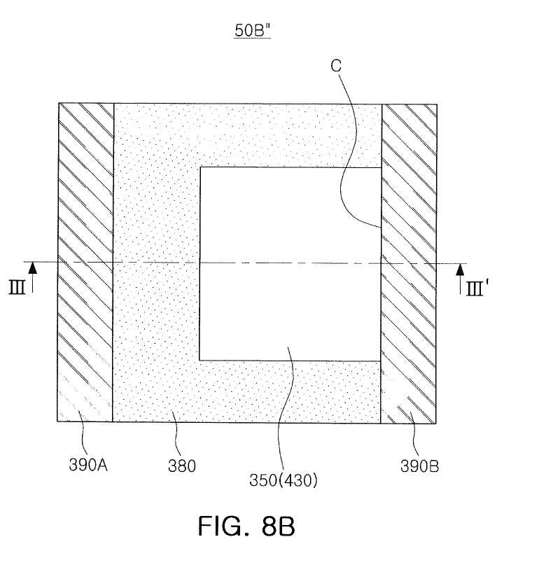

A stress relieving function of the reinforcing frame 390′ is satisfied when providing a surface allowing the reinforcing frame 390′ to be in contact simultaneously or before a resin molding portion or a semiconductor chip with a device of applying pressure to a lower surface of the lower structure. Thus, the reinforcing frame does not require a rectangular frame structure to be extended over an entire edge, unlike previous example embodiments. For example, a reinforcing frame used in some embodiments may only be formed on a portion of an edge (see FIGS. 8A and 8B), or may have a form in which a partial region of an edge is disconnected. The partial region, having been disconnected, may be used as an inlet of molding resin, in a similar manner to an opening in embodiments discussed above.

FIG. 8A is a side cross section illustrating an image sensor module according to some embodiments, and FIG. 8B is a plan view of a lower structure of the image sensor module illustrated in FIG. 8A.

Referring to FIGS. 8A and 8B, an image sensor module 50″ according to some embodiments may be understood as being similar to the image sensor module 50 illustrated in FIGS. 1 through 3, except that the reinforcing frame 390 is only disposed on two edges, opposing each other, in a lower surface of the upper structure 50A, and one surface of the semiconductor chip 350 is disposed to be in contact with an inner wall of the reinforcing frame 390. The description of the components of some embodiments may be referred to the description of the same or similar components of the image sensor module 50 illustrated in FIGS. 1 through 3, unless specifically stated otherwise.

In some embodiments, a lower structure 50B″ may include a first reinforcing frame 390A and a second reinforcing frame 390B provided as a pair of side surfaces of the lower structure 50B″, opposing each other. As discussed above, a reinforcing frame used in some embodiments is provided as two separate structures. The first reinforcing frame 390A and the second reinforcing frame 390B are located in both edges opposing each other and, thus, may be suitably used as a structure for relieving stress while protecting a region located therebetween when external pressure is applied.

Meanwhile, in a portion in which the first reinforcing frame 390A and the second reinforcing frame 390B are not located, a side surface of the lower structure 50B″ may be provided by a resin molding portion. The portion discussed above may be used as an inlet of molding resin for formation of the resin molding portion 380 in a similar manner to an opening of the previous example embodiment.

The first reinforcing frame 390A and the second reinforcing frame 390B may include a ceramic (for example, alumina) or metal (for example, SUS), having Young's modulus higher than Young's modulus of the resin molding portion 380. Furthermore, the ceramic or metal may have relatively high thermal conductivity, as compared to resin forming the resin molding portion 380.

In some embodiments, in a similar manner to embodiments discussed above, the semiconductor chip 350 may be disposed to be in contact with an inner wall of at least one (the second reinforcing frame 390B in some embodiments) of the first reinforcing frame 390A and the second reinforcing frame 390B. The second reinforcing frame 390B and the semiconductor chip 350 may have a single contact surface C. Through the contact surface C, the semiconductor chip 350, a memory element, may effectively radiate heat generated by the semiconductor chip 350 to the second reinforcing frame 390B in which thermal conductivity is relatively high, as compared to the resin molding portion 380.

The upper structure 50A, in which cracking may easily occur, is supported using the first reinforcing frame 390A and the second reinforcing frame 390B of the lower structure 50B″, so that durability of the image sensor module 50″ may be significantly enhanced. In addition, the first reinforcing frame 390A and the second reinforcing frame 390B may be used as a heat dissipating device for the semiconductor chip 350, a heat source.

As set forth above, according some embodiments of the present inventive concept, a reinforcement structure for strengthening a rear side of an image sensor module is provided to a molding portion of a lower structure, so pressure, applied when being fastened to a circuit board of a camera module, or durability against mechanical and thermal impact of an environment of use may be significantly improved.

While example embodiments have been shown and described above, it will be apparent to those skilled in the art that modifications and variations could be made without departing from the scope of the present disclosure, as defined by the appended claims.

What is claimed is:

1. An image sensor module, comprising:
a lower structure; and
an upper structure on the lower structure and including a semiconductor substrate, an image sensor being positioned on the semiconductor substrate,
wherein the lower structure includes:
a semiconductor chip on a region of a lower surface of the upper structure and connected to the image sensor;
a reinforcing frame along an edge of the lower surface of the upper structure; and
a resin molding portion between the reinforcing frame and the semiconductor chip,
wherein the reinforcing frame has a Young's modulus higher than a Young's modulus of the resin molding portion.

2. The image sensor module of claim 1, wherein the Young's modulus of the reinforcing frame is at least 50 Gpa.

3. The image sensor module of claim 2, wherein the reinforcing frame comprises one of a ceramic and a metal.

4. The image sensor module of claim 1, wherein a width of the reinforcing frame is at least 10% of a width of the lower structure.

5. The image sensor module of claim 4, wherein the width of the reinforcing frame is at least 900 μm.

6. The image sensor module of claim 1:
wherein the reinforcing frame includes a first frame and a second frame on a first pair of edges opposing each other, respectively; and
wherein the resin molding portion is exposed to a side surface of the lower structure, adjacent to a second pair of edges opposing each other, different from the first pair of edges.

7. The image sensor module of claim 1:
wherein the reinforcing frame includes a first frame and a second frame on a pair of edges, opposing each other, in the lower surface of the upper structure, respectively, and provided as side surfaces of the lower structure; and
wherein the resin molding portion is exposed to side surfaces, among side surfaces of the lower structure, in which the first frame and the second frame are not located.

8. The image sensor module of claim 1, wherein the reinforcing frame has a structure, along an entire edge of the lower surface of the upper structure and provided as side surfaces of the lower structure.

9. The image sensor module of claim 8:
wherein the reinforcing frame defines an opening therein in a same direction as a width; and
wherein the resin molding portion is extended to the opening.

10. The image sensor module of claim 1, wherein the semiconductor contacts with inner walls of the reinforcing frame, opposing each other.

11. The image sensor module of claim 1, further comprising at least one chip in the resin molding portion.

12. An image sensor module, comprising:
an upper structure including a first semiconductor substrate including an image sensor and a second semiconductor substrate including a logic circuit is formed; and
a lower structure on a lower surface of the upper structure having side surfaces that are substantially coplanar with side surfaces of the upper structure, adjacent thereto,
wherein the lower structure includes:
a semiconductor chip connected to the image sensor and the logic circuit;
a resin molding portion surrounding the semiconductor chip; and
a reinforcing frame providing side surfaces of the lower structure and surrounding the resin molding portion, and having a Young's modulus higher than a Young's modulus of the resin molding portion.

13. The image sensor module of claim 12:
wherein the reinforcing frame includes stainless steel; and
wherein the semiconductor chip has one of one side surface and both side surfaces opposing each other, disposed to be in contact with an inner wall of the reinforcing frame.

14. The image sensor module of claim 13:
wherein the reinforcing frame defines an opening passing therethrough in a width direction; and
wherein the opening is in a portion with which the semiconductor chip is not in contact.

15. The image sensor module of claim 12, wherein the semiconductor chip includes a memory chip.

16. The image sensor module of claim 12, wherein the reinforcing frame has Young's modulus of at least 50 Gpa and a width equal to at least 10% of a width of the lower structure.

17. An image sensor module, comprising:
an upper structure including a first semiconductor substrate including an image sensor and a second semiconductor substrate including a logic circuit; and
a lower structure on a lower surface of the upper structure having side surfaces that are substantially coplanar with side surfaces of the upper structure, adjacent thereto,
wherein the lower structure includes:
a first reinforcing frame and a second reinforcing frame provided as a first pair of side surfaces of the lower structure, opposing each other;
a semiconductor chip between the first reinforcing frame and the second reinforcing frame and connected to the image sensor and the logic circuit; and
a resin molding portion between the first reinforcing frame and the second reinforcing frame to surround the semiconductor chip and provided as a second pair of side surfaces of the lower structure, opposing each other, different from the first pair of side surfaces.

18. The image sensor module of claim 17, wherein the Young's modulus of the first and/or second reinforcing frame is higher than Young's modulus of the resin molding portion.

19. The image sensor module of claim 17, wherein the Young's modulus of the reinforcing is at least 50 Gpa and a width of the reinforcing frame is at least 900 μm.

20. The image sensor module of claim 17:
wherein the reinforcing frame comprises one of a ceramic and a metal; and
wherein the semiconductor chip contacts an inner wall of at least one of the first reinforcing frame and the second reinforcing frame.
